(19) United States
(12) Patent Application Publication
(10) Pub. No.: US 2016/0268967 A1
(43) Pub. Date: Sep. 15, 2016

(54) MODULAR UNIT FOR ATTACHMENT TO SOLAR PANEL

(71) Applicants: Roger WEBB, Sydney, New South Wales (AU); Maria WEBB, Sydney, New South Wales (AU)

(72) Inventors: Roger Webb, Cambridge, TAS (AU); Maria Webb, Cambridge, TAS (AU)

(21) Appl. No.: 15/022,271

(22) PCT Filed: Sep. 16, 2014
(86) PCT No.: PCT/AU2014/050233

§ 371 Date: Mar. 16, 2016

(30) Foreign Application Priority Data
Sep. 17, 2013 (AU) 2013903565
Dec. 18, 2013 (AU) 2013904950

(51) Int. Cl. H02S 40/44; F24J 2/24; H01L 35/30; H02S 10/10; H02S 40/42; H01L 31/0525

(52) U.S. Cl. CPC H02S 40/44; H02S 40/425; H01L 31/0525; H01L 35/30; H02S 10/10; F24J 2/24

(57) ABSTRACT

A modular unit attached to a solar panel. The modular unit comprises a heat exchanger having an inlet manifold and an outlet manifold and a plurality of spaced apart galleries extending there between, a plurality of thermoelectric modules disposed between the galleries and a plurality of heat sink tiles, the thermoelectric modules bonded to the heat sink tiles and clamped into abutment with the galleries. In use the modular unit is attached to the solar panel by bonding said heat sink tiles to said solar panel.

### TECHNICAL FIELD

The present invention relates to a modular unit for attachment to a solar panel. In particular, this invention is directed towards a modular unit comprising a heat exchanger and a plurality of thermoelectric modules. The modular unit when attached to a solar panel, can be used in a system or apparatus for generating electricity, and has a dual purpose of cooling the solar panel whilst able to generate electricity.

### BACKGROUND

A “solar panel” is a set of solar photovoltaic modules electrically connected and mounted on a supporting structure. A photovoltaic module is a packaged, connected assembly of solar cells. The solar module can be used as a component of a larger photovoltaic system to generate and supply electricity in commercial and residential applications, and as such solar panels are widely used throughout the world.

A photovoltaic system typically includes a panel or an array of photovoltaic modules, an inverter, and sometimes a battery and or solar tracker and interconnection wiring.

Each photovoltaic module is rated by its DC output power under standard test conditions, and these typically range from 100 to 320 watts.

One disadvantage of a solar panel is that as the temperature of the collecting surface increases, the efficiency of the solar panel significantly decreases. For instance, a solar panel which is rated to generate 100 watts at 25° C. will typically only produce about 85 watts when its operational surface temperature is about 40° C. Another disadvantage is that other components associated with the solar panel can over heat, or their operable life affected by heating.

Attempts have been made to improve the efficiency of solar panels/photovoltaic modules by cooling same. U.S. Pat. No. 4,361,717 (Gilmore et al.) dating back to 1982, discloses a fluid cooled photovoltaic cell, whist U.S. Pat. No. 5,197,291 (Levinson) dating back to 1993 discloses a thermoelectric module (Peltier module) powered by a solar panel to cool a battery which acts as a back-up power supply.

In more recent times it has been proposed to utilize the “thermoelectric effect” or “Seebeck effect” for cooling a photovoltaic module. One such arrangement is proposed in DE102008009979 (Perez), where a system is proposed for both cooling and generating electrical energy using Peltier modules. Another arrangement is proposed in US2011/0155214 (Lam) where a Peltier module is affixed thereto. Both these arrangements are inefficient.

DE102008009979 while proposing to improve efficiency would actually have the opposite effect. it discloses that the heat is evacuated from the rear of the Peltier modules and relies on the flow of cool air to evacuate the heat component passing through the Peltier modules. It also indicates that the air is circulated by an electric fan which is powered by the solar panel. However, in practice a photovoltaic solar panel will absorb vast quantities of heat over 1000 watts of heat per second. (from an average 100 watt sized panel). The Peltier modules in this disclosure will typically produce 5 watts of additional output. The electric fans needed to evacuate the volume of air to cool the rear of the Peltier modules to enable them to obtain the additional of 5 watts of power which would actually cost them some 25 watts of electrical fan use to move the volume of air required for cooling. As such the arrangement of DE102008009979 does not improve efficiency of the solar panel.

US2011/0155214 (Lam) also employs Peltier modules, but the arrangement relies on cooling fins on the rear of module to dissipate heat to the environment. This results in very inefficient air cooling of the panel.

A temperature differential of at least about 10° C. is required for Pettier modules to make any useful electrical energy output. The abovementioned prior art Peltier module arrangements could not provide a temperature differential of this magnitude, and therefore are not of practical use.

There is also an oversupply of conventional solar panels on the world market, primarily because of the massive amount of stock produced in China in recent years, and the waning solar subsidies in major markets such as Europe. As such it is desirable to provide a unit that can be attached to or otherwise be used with conventional solar panels, which will improve the efficiency of generating electricity.

The present invention seeks to provide a modular unit for attachment to a solar panel which will ameliorate or overcome at least one of the deficiencies of the prior art.

### SUMMARY OF INVENTION

According to a first aspect the present invention consists in a modular unit for attachment to a solar panel, said modular unit comprising:
a heat exchanger having an inlet manifold and an outlet manifold and a plurality of spaced apart galleries extending there between;
a plurality of heat sink tiles; and
a plurality of thermoelectric modules having first sides bonded to said plurality of heat sink tiles, and opposed second sides abutted against said galleries of said heat exchanger, and wherein a plurality fasteners are used to extend from said heat sink tiles through said heat exchanger to at least one clamp member for clamping said galleries of said heat exchanger in abutment to said thermoelectric modules.

Preferably at least one of said galleries comprises a tubular member which in use is for coolant fluid to pass through, said tubular member attached to one side of a heat sink pad, and an opposed side of said heat sink pad is abutted against one said thermoelectric modules.

Preferably at least one spacer is disposed between said heat sink pad and said clamp member.

Preferably expansion gaps are provided between adjacent heat sink tiles.

Preferably at least one flexible connection plate spans at least one of said expansion gaps.

Preferably in order to attach said modular unit to said solar panel, said heat sink tiles are bonded to said solar panel.

Preferably said heat sink tiles of said modular unit are bonded to solar panel, and in use said heat exchanger is connected to a circulation system which allows coolant to flow through said heat exchanger, and a heat differential between the first sides of said thermoelectric modules and opposed second sides reduces temperature of said solar panel.

Preferably said heat sink tiles of said modular unit are bonded to solar panel, and in use said heat exchanger is connected to a circulation system which allows coolant to flow through said heat exchanger, and an electronic control unit is electrically connected to both said plurality of thermoelectric modules and said solar panel, and said electronic control unit is used for distribution and storage of electrical charge.

According to a second aspect the present invention consists in a modular unit for attachment to a solar panel, said modular unit comprising:
a heat exchanger having an inlet manifold and an outlet manifold and a plurality of spaced apart galleries extending there between, said heat exchanger clamped in abutment against a plurality of thermoelectric modules which are bonded against the first sides of a plurality of spaced apart heat sink tiles, and wherein opposed sides of said plurality of spaced apart heat sink tiles provide attachment surfaces for bonding same to said solar panel.

According to a third aspect the present invention consists in a modular unit for attachment to a solar panel, said modular unit comprising a heat exchanger having an inlet manifold and an outlet manifold and a plurality of spaced apart galleries extending there between, a plurality of thermoelectric modules disposed between said galleries and a plurality of heat sink tiles, said thermoelectric modules bonded to said heat sink tiles and clamped into abutment with said galleries, and in use said modular unit is attached to said solar panel by bonding said heat sink tiles to said solar panel.

According to a fourth aspect the present invention consists in a modular unit in combination with a solar panel, said modular unit comprising:
a heat exchanger having an inlet manifold and an outlet manifold and a plurality of spaced apart galleries extending there between, said heat exchanger clamped in abutment against a plurality of thermoelectric modules which are bonded against the first sides of a plurality of spaced apart heat sink tiles, and opposed sides of said plurality of spaced apart tiles provide attachment surfaces to which said solar panel is bonded.

### BRIEF DESCRIPTION OF DRAWINGS

FIG. 1 shows a schematic view of a system for generating electricity in accordance with a first embodiment in which a modular unit of the present invention can be utilised;

FIG. 2 is an enlarged schematic view of the solar panel, thermoelectric modules and first heat exchanger connected thereto of the system depicted in FIG. 1;

FIG. 2a is an enlarged detail of an in-series connection of two thermoelectric modules shown in circle A of FIG. 2.

FIG. 3 is an enlarged side schematic view and further enlarged detail of the solar panel, thermoelectric modules and first heat exchanger connected thereto of FIG. 2;

FIG. 3a is an enlarged detail of the photovoltaic layer of the solar panel and two thermoelectric modules and first heat exchanger shown in circle B of FIG. 3.

FIG. 4 is an enlarged side schematic. view of a solar panel in a system far generating electricity in accordance with a second embodiment of the present invention;

FIG. 4a is an enlarged detail of a thermoelectric module and first heat exchanger connected thereto shown in circle C of FIG. 4.

FIG. 5 is a schematic view of a solar panel and third heat exchanger assembly, in accordance with a modified embodiment of the system depicted in FIG. 1.

FIG. 5a is an enlarged detail of the third heat exchanger assembly shown in circle D of FIG. 5.

FIG. 5b is an enlarged detail of the third heat exchanger assembly shown in ellipse E of FIG. 5.

FIG. 6 is an elevational view of a solar panel for use with the modular unit of the present invention.

FIG. 7 depicts a front elevation of the modular unit of the present invention for attachment to solar panel shown in FIG. 6.

FIG. 8 depicts a side elevation of the modular unit shown in FIG. 7.

FIG. 9 depicts a side elevation of the modular unit shown in FIG. 7.

FIG. 10 is an enlarged cross sectional schematic of the modular unit.

### DESCRIPTION OF PREFERRED EMBODIMENTS

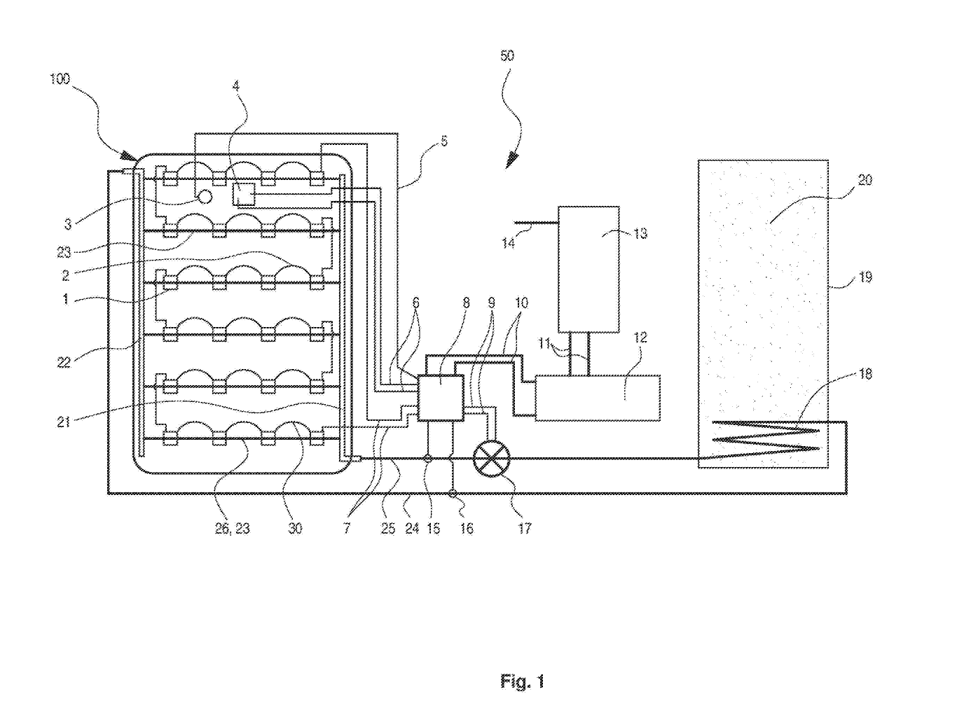

FIGS. 1 to 3 depict a system 50 for generating electricity comprising a solar 100 and an array of thermoelectric modules (Peltier modules) 1 fixed thereto.

Solar panel 100 is a conventional set of solar photovoltaic modules, represented by photovolataic layer 200, electrically connected and mounted on a supporting structure, and operably connected to an electronic control unit (ECU) 8 via leads 6. Thermoelectric modules 1 are also operably connected to ECU 8 via leads 7. A battery (or bank of batteries) 12 is also operably connected to ECU 8 via leads 10.

System 50 also comprises a circulation system including a first heat exchanger (Peltier water gallery exchanger) 26, circulation pipe network 24, 25, circulation pump 17 and second heat exchanger 18 disposed within water storage tank 19. Water, or some other coolant, is able to be pumped through circulation pipe network 24, 25 between first heat exchanger 26 and second heat exchanger 18.

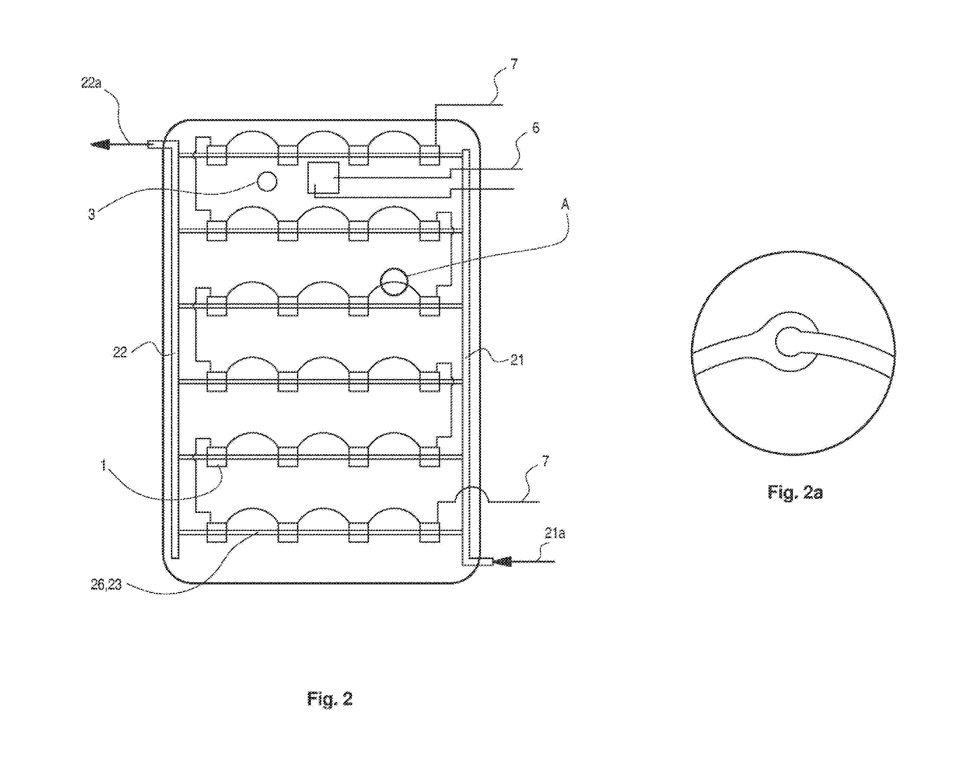

First heat exchanger 26 has an inlet manifold 21 and outlet manifold 22, and a plurality of galleries 23 extending there between. In FIG. 2, water is shown entering inlet manifold 21 as arrow 21a, and exiting outlet manifold 22 as arrow 22a.

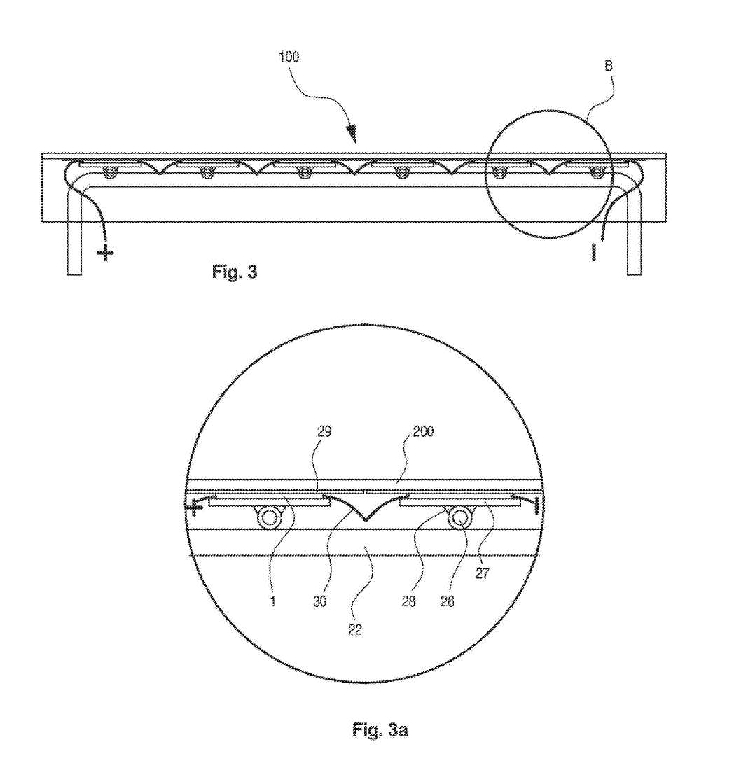

As best seen in FIGS. 3 and 3a, each thermoelectric module 1 is fixed to the rear of the photovoltaic layer 200 of solar panel 100 via heat sink tiles 29. In this embodiment conventional commercially thermoelectric modules 1 are used, and heat sink tiles 29 made of aluminium, are used between modules 1 and layer 200. Adhesive is used to bond both module 1 and layer 200 to tile 29.

Preferably heat sink tiles 29 should be a maximum size of about 150 mm×150 mm, to avoid damage or failure of the photovoltaic layer 200. This is because the different materials of the photovoltaic layer 200 and tiles 29 expand and contract at different rates. Gaps between tiles 29 are needed to allow for expansion and shrinkage. Preferably, in this embodiment each tile 29 lies within the circuit boundary lines of photovoltaic layer 200 on the opposing front side. In this embodiment a solar panel is rated at 100 watts, with twenty-four thermoelectric modules 1, with each of those modules having an aluminium heat sink tile 29 correspondingly attached to its rear. As also can be seen in FIG. 3a, first heat exchanger 26 has a contact pad 27 welded thereto, via weld 28. Contact pad 27 which is positioned against the rear side of thermoelectric module 1 ensures heat transfer between module 1 and water (coolant) passing through first heat exchanger 26. Each module 1 has a first front side in direct contact with (bonded to) solar panel 100, and the opposed rear side of each module 1 is in direct contact (bonded to) a gallery 23 of first heat exchanger 26.

Surface temperature sensor 3 disposed on solar panel 1, senses change in temperature of the “photovoltaic operational surface” of panel 1. Sensor 3 is operably connected to ECU 8 via lead 5.

Pump 17 is operably connected to ECU 8 via power cable 9 such that its operation can be controlled thereby. When a predetermined temperature has been reached, say about 25° C., ECU 8 switches water circulating pump 17 to “on”, causing cool water to flow through pipe 24 into first heat exchanger 26 across the rear of the panel and the rear of modules 1 and pipe 25 and heat exchanger 18 in water tank 19. The “cool water” in heat exchanger 26 causes a heat differential to occur across thermoelectric modules 1 (heat on front “panel” facing side and cold on rear “exchanger” facing side). As a result of this heat differential an electrical charge is generated by modules 1.

Thermoelectric modules 1 are connected in series via cable 2, and each module I can preferably generate between 0.5 V and 0.75 V. Twenty four modules 1 connected in series will provide in excess of 12 volts required by a 12V solar panel. The resulting electrical charge from modules 1 is delivered into ECU 8 via leads 7 for distribution and/or storage. The resulting electricity generated via panel 100 is delivered to ECU 8 for distribution and/or storage via electrical cables 6. The resulting heat is removed from the rear of modules 1 via heat exchanger 26 and pipe network 24, 25, and circulated by pump 17, such that it is pumped through heat second exchanger unit 18, whereby the “heat energy” of the circulating cooling water is transferred into stored water 20, in tank 19, thereby elevating its temperature for future use Electrical energy generated is stored in battery 12, and then adapted to mains supply voltage via inverter 13 and connected to grid (not shown) via cable 14.

in the abovementioned embodiment the “coolant” is preferably water, but may include conventional coolant additives such as ethylene glycol or other heat transfer agents, such as those commonly used in air conditioners or car engine cooling.

The abovementioned system 50 has a two-fold advantage. Firstly, the circulating water(coolant)coolant passing through first heat exchanger 26 ensures heat is drawn away from solar panel 100 via thermoelectric modules 1, which decreases the temperature in panel 100 and therefore improves the electrical generating efficiency of same. Secondly, the heat differential occurring within thermoelectric, modules 1 also generates electricity.

System 50 may be retro-fitted to existing conventional solar panels 100 or purposefully constructed.

A preferable feature of the present invention is that thermoelectric modules 1 are in direct contact to photovoltaic layer 200 of solar panel 100 and to first heat exchanger 26. By “direct contact”, we mean that there are “no air gaps” between thermoelectric module land solar panel 100, as is the case in the prior art DE102008009979 (Perez), and the dissipation of heat on the rear side is not reliant on environmental air dissipation as is the case in the prior art US2011/0155214 (Lam), but rather heat exchange to the coolant is through heat exchanger 26, which is bonded to module 1. As mentioned in the “Background”, there must be a temperature differential of at least about 10° C. for thermoelectric modules 1 to make any useful electrical energy output. Because of the “direct contact” in the present invention this temperature differential is possible, and useful electrical energy output is possible. As earlier mentioned in the “Background”, the abovementioned prior art thermoelectric (Peltier) module arrangements could not provide a temperature differential of this magnitude, and therefore are not of practical use.

in this specification “direct contact” means that module is in direct contact (or bonded) with layer 200 of panel 100 and heat exchanger 26, or has some other heat conductive “intermediate means”, such as aluminium tile 29 to create the bond. Tile 29 is used in this embodiment, because it is an easy way to bond a commercially available thermoelectric module 1 to solar panel 100. However, it should be understood, that purposely made thermoelectric modules may be used which have a suitable contact surface that allows for them to be glued directly to panel 100 without using separate tiles.

It must be understood that in operation, providing there is a heat differential between one side of thermoelectric module 1 and the other side, electricity can be generated. This means, in times of “no sunlight” or night time, and providing the ambient air temperature is greater than the coolant at the rear of thermoelectric module 1, electricity can be generated from panel 100. In other words, the photovoltaic surface area of panel 100 will act as a heat absorption unit or heat sink.

In a further embodiment it should be understood that the now heated stored water 20 can be put to use. In a reverse operation the energy stored in hot water can be used to heat the “coolant”. This means thermoelectric modules 1 of system 50 may be used in reverse. In times of cold atmospheric air temperatures, the “coolant” being heated by stored water 20 as it passes through second heat exchanger 18, will now be warmer than panel 100, and the resulting temperature differential will cause thermoelectric modules to generate electricity at night as well as during the daytime operation of solar panel 100.

It should also be understood that thermoelectric modules 1 can be used in reverse as a “heat pump” to cool or heat the circulating “coolant”. To do this the stored electrical energy in battery 12 can be used to operate thermoelectric modules 1 as heat pumps.

It should also be understood that excess electrical energy may be used for additional cooling of panel 100 via thermoelectric modules 1.

In the abovementioned embodiment shown in FIGS. 1 to 3, twenty-four single thermoelectric modules 1, are depicted in series as a fixed array. However, it should be understood that in another embodiment modules 1 may be operated in any single location, in a tier or stacked arrangement to improve thermoelectric reaction.

It should also be understood that in another not shown embodiment, thermoelectric modules may be connected into pairs or groups, where each pair or group of modules are in an operating circuit with a capacitor. This is to allow a build up of electrical energy over time to be released sequentially at a higher volume or capacity of electrical energy to be used or stored over and above what thermoelectric modules 1 are able to produce when directly coupled in series.

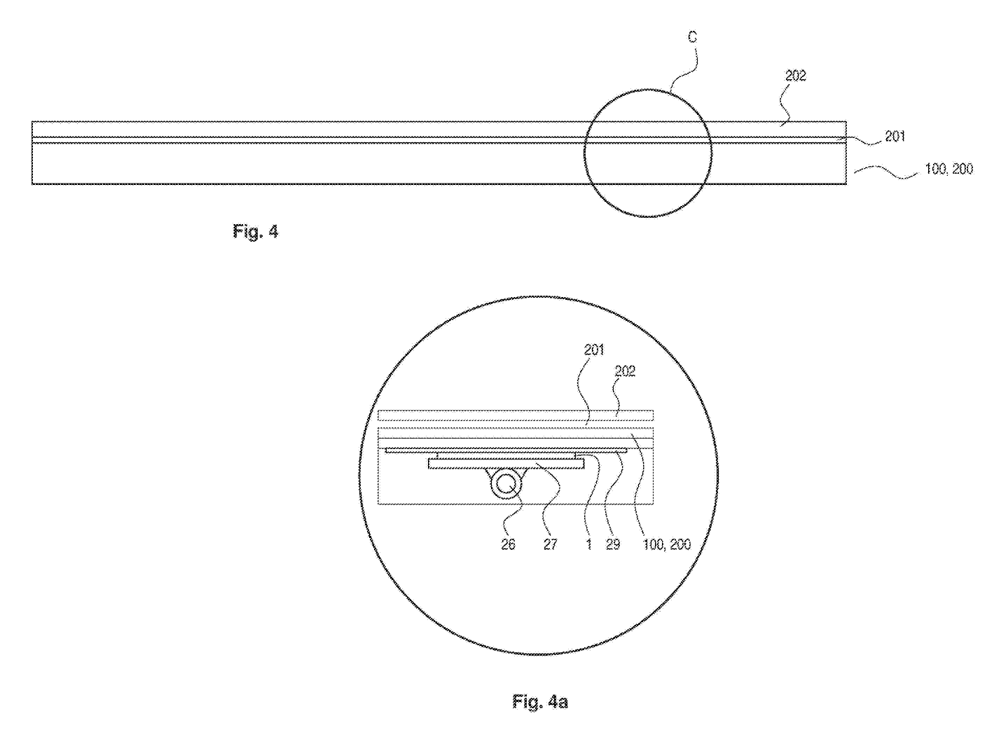

In a further embodiment as shown in FIG. 4, a further modification can be made. An additional second layer of protective glass 202, can overlay photovoltaic layer 200 of solar panel 100, with a cavity 201 disposed between second layer of protective glass 202 and panel 200, Electrical energy generated by thermoelectric modules 1 may be used to power at least one electric fan (not shown) to propel a flow of cool air to be directed through cavity 201 across the face of photovoltaic layer 200, thus evacuating heat there from.

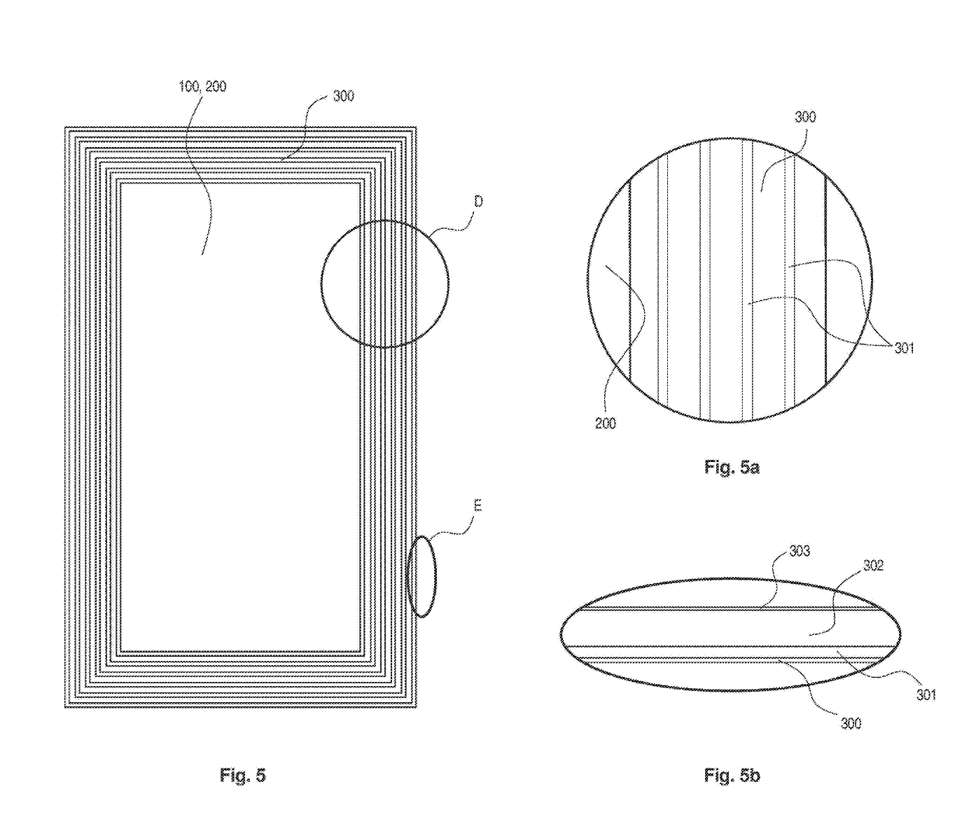

In a further embodiment as shown in FIGS. 5, 5a and 5b, photovoltaic layer 200 of panel 100 is surrounded by a superheating “heat absorption” heat exchanger assembly 300. In this embodiment heat exchanger 300 is preferably made from aluminium, which comprises heat exchanging fluid filled tubes (or gallery) 301. These heat exchanging fluid filled tubes 301 are either inlaid or attached to the body of heat exchanger assembly 300.

Preferably heat exchanger assembly 300 is preferably covered by a see-through glass covering 303 there providing a void (or cavity) 302. Heat exchanger assembly 300 would work in corporation with system 1 of the abovementioned embodiment. When coolant (water or other fluid) as is the case in the first embodiment, draws heat away when exiting heat exchanger, this heated fluid is first fed into tubes 301 and upon circulating through gallery 301 heat is exchanged and carried away, boosting the heat contained over and above what normally can be obtained from the rear of solar pane 100, thereby causing the coolant fluid to be superheated before it moves to second heat exchanger 18. This provides more heat energy to water 20 in tank 19.

In the abovementioned embodiments, thermoelectric modules 1 are preferably fixed to the rear of the photovoltaic layer 200 of solar panel 100. However it should be understood that in other not shown embodiments they could be attached to other areas of solar panel 100.

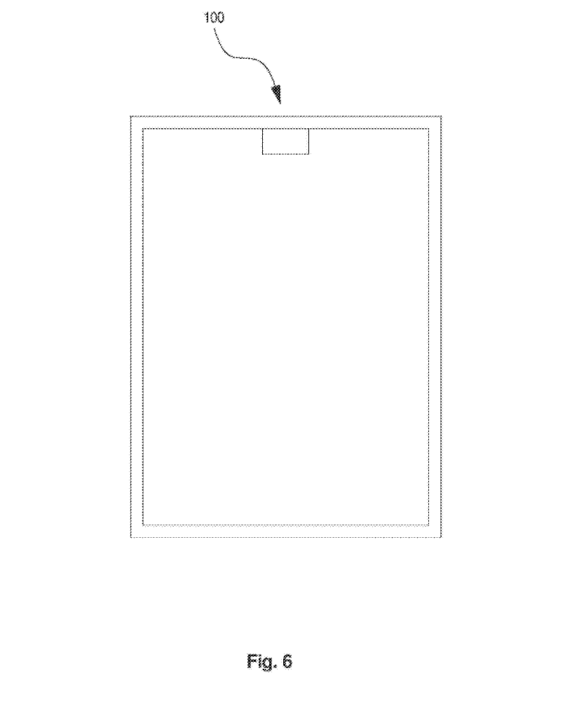

FIGS. 6 to 10 depict a further embodiment which allows the important components of the earlier described embodiment, namely heat exchanger 26 and thermoelectric modules I, and preferably other components to be constructed as modular unit 123 which can be readily constructed alone and attached to a solar panel 100.

Solar panel 100 may preferably be conventional, and comprise a photovoltaic cell 38 disposed between an insulation layer 39 and protection glass layer 40.

Modular unit 123 comprises a heat exchanger 26 having an inlet manifold 31 and an outlet manifold 32 and a plurality of spaced apart galleries 23 extending there between, a plurality of heat sink tiles 29 and a plurality of thermoelectric modules 1. In this embodiment there are twenty four tiles 29, and twenty four thermoelectric modules 1 associated therewith. In this embodiment heat sink tiles 29 are preferably made of aluminium.

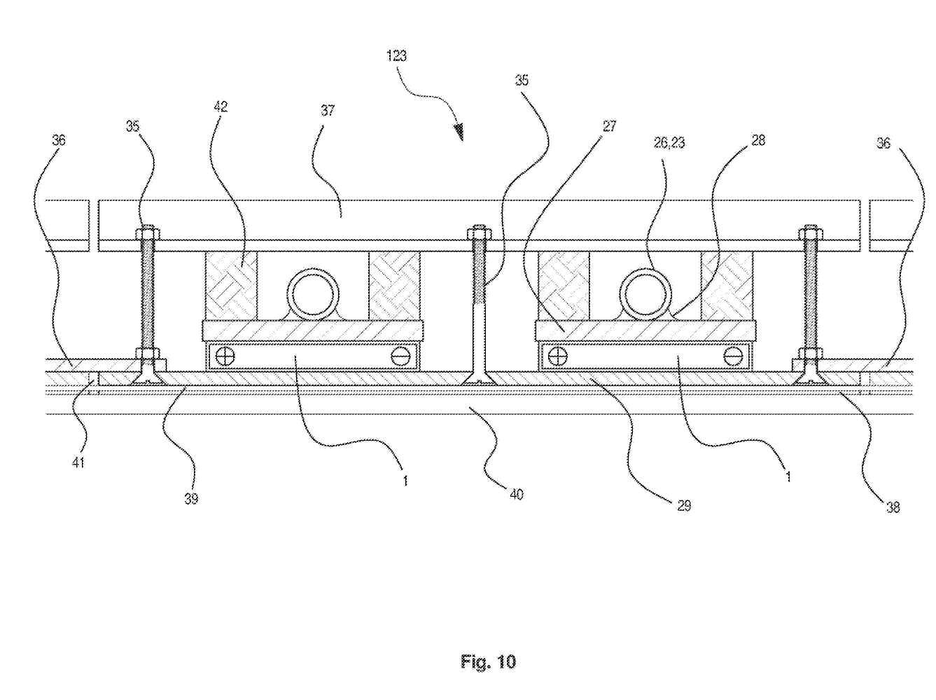

Heat sink tiles 29 are arranged in a “grid array” as best seen in FIG. 9, and are spaced apart such that expansion gaps 41 exist there between. Each heat sink tile 29 has a thermoelectric module 1 bonded thereto on one side. By “directly bonding” thermoelectric modules 1 to heat sink tiles 29, this improves thermal conductivity there between.

Each gallery 23 of heat exchanger 26 comprises a “tubular member”, best seen in FIG. 10, welded by weld 28 to a first side of heat sink pad 27. The “tubular member” of gallery 23 is the conduit through which coolant fluid passes there through when heat exchanger 26 is in use. The opposed side of heat sink pad 27 is abutted against a thermoelectric module 1 as best seen in FIG. 10. A thermally conductive “grease” (not shown), or other similar substance may preferably be applied at the interface between heat sink pad 27 and thermoelectric module I to improve thermal transfer there between.

By means of bridge clamps 37, spacers 42 and threaded fasteners 35, heat sink pads 27 of galleries 23 are clamped to ensure that they are maintained in abutment with thermoelectric modules 1. As can be seen in FIG. 10 the head of each male threaded fastener (screw) 35 is seated in a recess in heat sink tile 29, and each fastener 35 passes in between galleries 23 (through heat exchanger 26) and is secured to a bridge clamp 37 by a “nut” of female threaded fastener 35. Spacers 42, preferably of plastic material are disposed and extend between each heat sink pad 27 and bridge clamp 37.

Fasteners 35 are also utilized to secure flexible connection plates 36 which interconnect heat sink tiles 29 and span over expansion gaps 41. Flexible connection plates 36 allow the expansion and contraction process to take place via expansion gaps 41. In addition, flexible connection plates 36, allow the manufacture of the entire structure of modular unit 123 to be carried out freestanding remote from solar panel 100.

The abovementioned clamping ensures a good an even thermal contact between heat sink pads 27 and thermoelectric modules 1. The use of multiple fasteners (anchor points) 35 with individual bridge damps 37 allows for an even load distribution on heat sink tiles 29 and eliminates or minimizes “delamination”. The use of plastic blocks 42 minimizes the thermal transfer into bridge clamps 37.

Each heat sink tile 29 has a thermoelectric module 1 on one side, and the other opposed side of each tile 29 is provided as an “attachment surface”. In order to attach a modular unit 123 to a solar panel 100, the attachment surfaces of tiles 29 may be bonded (glued) in direct contact with the insulation layer 39 of solar panel 100.

One of the advantages of modular unit 123 is that it can be manufactured as a stand-alone unit and readily stored and shipped for future attachment to a conventional solar panel 100. Once attached (bonded) to a solar panel 100, the “combination” of modular unit 123 and solar panel 100, can be used in system 50 described in the earlier embodiment with heat exchanger 26 of modular unit 123 being connected to circulation network 24, 25 so that water (coolant) flows through galleries 23.

It is envisaged that the width (or thickness) of modular unit 123 in this embodiment will be about 35 mm, so once bonded to a conventional solar panel 100 (having a thickness of about 8 mm), the overall width of the combination should be able to be kept within about 45 mm.

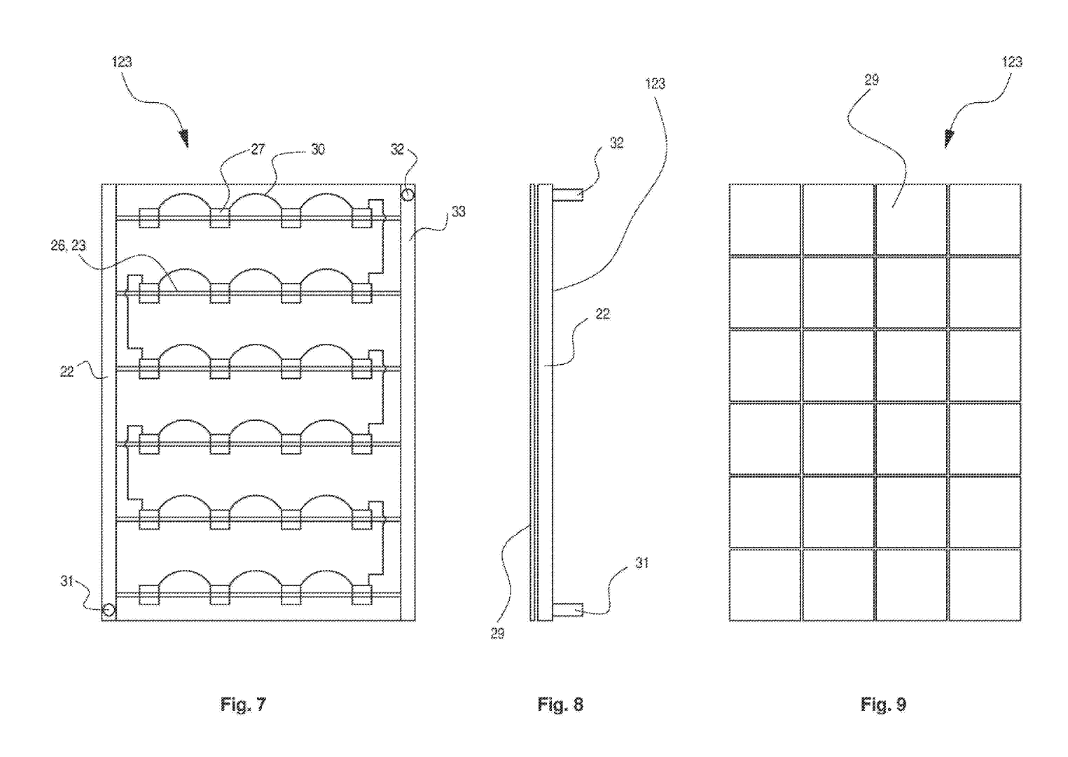

In the abovementioned embodiment twenty four thermoelectric modules 1 are used with four thermoelectric modules 1 associated with each of the six galleries 23, best shown in FIG. 7. However, it should be understood that not all the galleries 23 need to have associated thermoelectric modules 1, and the number of galleries 23, thermoelectric modules 1 and therefore heat sink pads 27 and tiles 29 may vary in other not shown embodiments.

The terms “comprising” and “including” (and their grammatical variations) as used herein are used in inclusive sense and not in the exclusive sense of “consisting only of”.

1. A modular unit, for attachment to a solar panel, said modular unit comprising:
a heat exchanger having an inlet manifold and an outlet manifold and a plurality of spaced apart galleries extending there between;
a plurality of heat ink tiles; and
a plurality of thermoelectric modules having first sides bonded to said plurality of heat sink tiles, and opposed second sides abutted against said galleries of said heat exchanger, and wherein a plurality fasteners are used to extend from said heat sink tiles through said heat exchanger to at least one damp member for clamping said galleries of said heat exchanger in abutment to said thermoelectric modules.

2. A modular unit for attachment to a solar panel, as claimed in claim 1, wherein at least one of said galleries comprises a tubular member which in use is for coolant fluid to pass through, said tubular member attached to one side of a heat sink pad, and an opposed side of said heat sink pad is abutted against one said thermoelectric modules.

3. A modular unit for attachment to a solar panel, as claimed in claim 2, wherein at least one spacer is disposed between said heat sink pad and said clamp member.

4. A modular unit for attachment to a solar panel as claimed in claim 1, wherein expansion gaps are provided between adjacent heat sink tiles.

5. A modular unit for attachment to a solar panel as claimed in claim 4, wherein at least one flexible Connection plate spans at least one of said expansion gaps.

6. A modular unit for attachment to a solar panel as claimed in claim 1, wherein in order to attach said modular unit to said solar panel, said heat sink tiles are bonded to said solar panel.

7. A modular unit as claimed in claim 1, wherein said heat sink tiles of said modular unit are bonded to solar panel, and in use said heat exchanger is connected to a circulation system which allows coolant to flow through said heat exchanger, and a heat differential between first sides of said thermoelectric modules and opposed second sides reduces temperature of said solar panel.

8. A modular unit as claimed in claim 1, wherein said heat sink tiles of said modular unit are bonded to solar panel, and in use said heat exchanger is connected to a circulation system which allows coolant to flow through said heat exchanger, and an electronic control unit is electrically connected to both said plurality of thermoelectric modules and said solar panel, and said electronic control unit is used for distribution and storage of electrical charge.

9. A modular unit for attachment to a solar panel, said modular unit comprising:
a heat exchanger having an inlet manifold and an outlet manifold and a plurality of spaced apart galleries extending there between, said heat exchanger clamped in abutment against a plurality of thermoelectric modules which are bonded against the first sides of a plurality of spaced apart heat sink tiles, and wherein opposed sides of said plurality of spaced apart heat sink tiles provide attachment surfaces for bonding same to said solar panel.

10. A modular unit for attachment to a solar panel, said modular unit comprising a heat exchanger having an inlet manifold and an outlet manifold and a plurality of spaced apart galleries extending there between, a plurality of thermoelectric modules disposed between said galleries and a plurality of heat sink tiles, said thermoelectric modules bonded to said heat sink tiles and clamped into abutment with said galleries, and in use said modular unit is attached to said solar panel by bonding said heat sink tiles to said solar panel.

11. A modular unit in combination with a solar panel, said modular unit comprising:
a heat exchanger having an inlet manifold and an outlet manifold and a plurality of spaced apart galleries extending there between, said heat exchanger clamped in abutment against a plurality of thermoelectric modules which are bonded against the first sides of a plurality of spaced apart heat sink tiles, and opposed sides of said plurality of spaced apart tiles provide attachment surfaces to which said solar panel is bonded.
